(19) United States
(12) Patent Application Publication
(10) Pub. No.: US 2022/0100078 A1
(43) Pub. Date: Mar. 31, 2022

(54) DEVICES AND METHODS FOR VARIABLE ETCH DEPTHS

(71) Applicant: Applied Materials, Inc., Santa Clara, CA (US)

(72) Inventors: M. Arif Zeeshan, Manchester, MA (US); Ross Bandy, Milton, MA (US); Peter F. Kurunczi, Cambridge, MA (US); Shantanu Kallakuri, Ithaca, NY (US); Thomas Soldi, West Simsbury, CT (US); Joseph C. Olson, Beverly, MA (US)

(73) Assignee: Applied Materials, Inc., Santa Clara, CA (US)

(21) Appl. No.: 17/032,520

(22) Filed: Sep. 25, 2020

(51) Int. Cl. G03F 1/36; G03F 1/80; G03F 1/70; G03F 1/74

(52) U.S. Cl. CPC G03F 1/36; G03F 1/74; G03F 1/70; G03F 1/80

(57) ABSTRACT

Methods and devices for producing substrates with variable height features are provided. In one example, a proximity mask may include a plate positioned over a substrate, wherein at least a portion of the plate is separated from the substrate by a distance. The plate may include a first opening and a second opening, wherein the first opening is defined by a first perimeter having a first shape, wherein the second opening is defined by a second perimeter having a second shape, and wherein the first shape is different than the second shape.

### FIELD OF THE DISCLOSURE

The present disclosure generally relates to processing of substrates. More specifically, the disclosure relates to devices and methods for producing variable-depth grating materials.

### BACKGROUND OF THE DISCLOSURE

Optical elements such as optical lenses have long been used to manipulate light for various advantages. Recently, micro-diffraction gratings have been utilized in holographic and augmented/virtual reality (AR and VR) devices. One particular AR and VR device is a wearable display system, such as a headset, arranged to display an image within a short distance from a human eye. Such wearable headsets are sometimes referred to as head mounted displays, and are provided with a frame displaying an image within a few centimeters of the user's eyes. The image can be a computer-generated image on a display, such as a micro display. The optical components are arranged to transport light of the desired image, where the light is generated on the display to the user's eye to make the image visible to the user. The display where the image is generated can form part of a light engine, so the image generates collimated light beams guided by the optical component to provide an image visible to the user.

The optical components may include structures with different slant angles, such as fins of one or more gratings, on a substrate, formed using an angled etch system. One example of an angled etch system is an ion beam chamber that houses an ion beam source. The ion beam source is configured to generate an ion beam, such as a ribbon beam, a spot beam, or full substrate-size beam. The ion beam chamber is configured to direct the ion beam at an angle relative to a surface normal of a substrate to generate a structure having a specific slant angle. Changing the slant angle of the structure to be generated by the ion beam requires substantial hardware reconfiguration of the of the ion beam chamber.

Forming optical devices that include different structures having different depths across the surface of the substrate has conventionally been performed using gray-tone lithography. However, gray-tone lithography is a time-consuming and complex process, which adds considerable costs to devices fabricated using the process.

Accordingly, improved methods and related equipment are needed for forming optical devices that include different structures with different slant angles and/or different depths across a single substrate.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

According to one embodiment, a proximity mask may include a plate positioned over a substrate, wherein at least a portion of the plate is separated from the substrate by a distance, and a first opening and a second opening formed through the plate. The first opening may be defined by a first perimeter having a first shape, wherein the second opening is defined by a second perimeter having a second shape, and wherein the first shape is different than the second shape.

According to another embodiment, a method may include providing a proximity mask over a substrate, wherein the proximity mask includes a plate separated from the substrate by a distance, and wherein the plate includes a first opening and a second opening. The method may further include etching the substrate through the first and second openings to recess a first processing area and a second processing area, and etching the substrate to form a plurality of structures oriented at a non-zero angle with respect to a perpendicular to a plane defined by a top surface of the substrate.

According to another embodiment, a method may include providing an ion beam source within a chamber, wherein the chamber is operable to deliver an ion beam to a substrate, and providing a proximity mask over the substrate, wherein the proximity mask includes a plate separated from the substrate by a distance, and wherein the plate includes a first opening and a second opening. The method may further include etching the substrate through the first and second openings to recess a first processing area and a second processing area, and etching the substrate to form a plurality of structures oriented at a non-zero angle with respect to a perpendicular to a plane defined by a top surface of the substrate.

### BRIEF DESCRIPTION OF THE DRAWINGS

The accompanying drawings illustrate exemplary approaches of the disclosure, including the practical application of the principles thereof, as follows:

FIG. 1 is a perspective, frontal view of an optical device, according to embodiments of the present disclosure;

FIG. 2A is a side, schematic cross-sectional view of an angled etch system, according to embodiments of the present disclosure;

FIG. 2B is a top, schematic cross-sectional view of the angled etch system shown in FIG. 2A, according to embodiments of the present disclosure;

FIG. 3A depicts a side, cross sectional view of an optical grating component formed from a substrate, according to embodiments of the disclosure;

FIG. 3B depicts a frontal view of the optical grating component of FIG. 3A, according to embodiments of the present disclosure;

FIG. 4A is a top view of an optical grating device and proximity mask according to embodiments of the present disclosure;

FIG. 4B is a side cross-sectional view of the optical grating device and proximity mask, taken along cutline B-B of FIG. 4A, according to embodiments of the present disclosure;

FIG. 5 is a side cross-sectional view of the optical grating device during an etch process according to embodiments of the present disclosure;

FIG. 6 is a side cross-sectional view of the optical grating device after the etch process according to embodiments of the present disclosure;

FIG. 7 is a side cross-sectional view of the optical grating device during an etch process according to embodiments of the present disclosure;

FIG. 8 is a side cross-sectional view of the optical grating device after the etch process according to embodiments of the present disclosure;

FIG. 9 is a side cross-sectional view of an optical grating device after the etch process according to embodiments of the present disclosure;

FIG. 10 depicts a proximity mask according to embodiments of the present disclosure;

FIG. 11A depicts a top view of a portion of a device including a stepped feature according to embodiments of the present disclosure;

FIG. 11B is a side cross-sectional view of the device and stepped feature, taken along cutline B-B of FIG. 11A, according to embodiments of the present disclosure;

FIGS. 12A-12F depict various stepped features according to embodiments of the present disclosure;

FIG. 13 is a flowchart of a method according to embodiments of the present disclosure;

FIG. 14A demonstrates a proximity mask, with a centered opening, provided over a mask layer and a wafer, according to embodiments of the present disclosure;

FIG. 14B demonstrates a proximity mask, with an off-centered opening, provided over a mask layer and a wafer, according to embodiments of the present disclosure;

FIG. 15 depicts a proximity mask of a device according to another embodiment of the present disclosure; and

FIG. 16 demonstrates various features of proximity masks according to embodiments of the present disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Devices, systems, and methods in accordance with the present disclosure will now be described more fully hereinafter with reference to the accompanying drawings, where various embodiments are shown. The devices, systems, methods may be embodied in many different forms and are not to be construed as being limited to the embodiments set forth herein. Instead, these embodiments are provided so the disclosure will be thorough and complete, and will fully convey the scope of the apparatuses, systems, and methods to those skilled in the art.

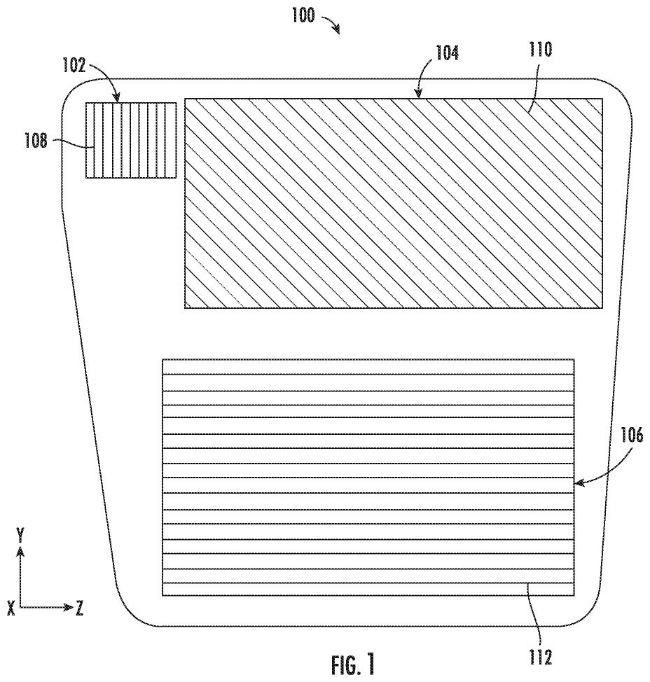

FIG. 1 is a perspective, frontal view of a device 100, such as an optical device, according to embodiments of the present disclosure. Examples of the optical device 100 include, but are not limited to, a flat optical device and a waveguide (e.g., a waveguide combiner). The optical device 100 includes one or more structures, such as gratings. In one embodiment, which can be combined with other embodiments described herein, the optical device 100 includes an input grating 102, an intermediate grating 104, and an output grating 106. Each of the gratings 102, 104, 106 includes corresponding structures 108, 110, 112 (e.g., fins). In one embodiment, which can be combined with other embodiments described herein, the structures 108, 110, 112 and depths between the structures include sub-micron critical dimensions (e.g., nano-sized critical dimensions), which may vary in one or more dimensions across the optical device 100.

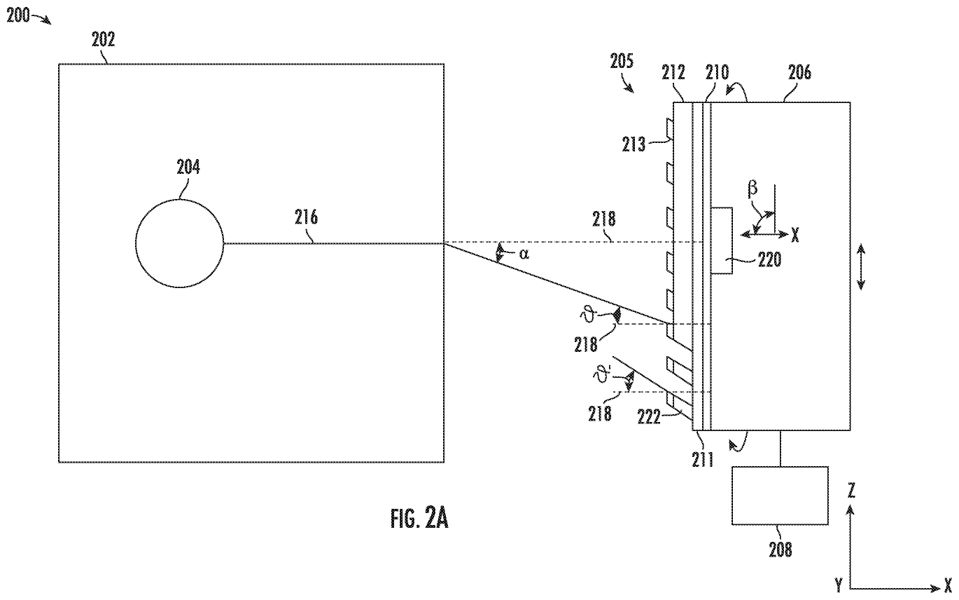

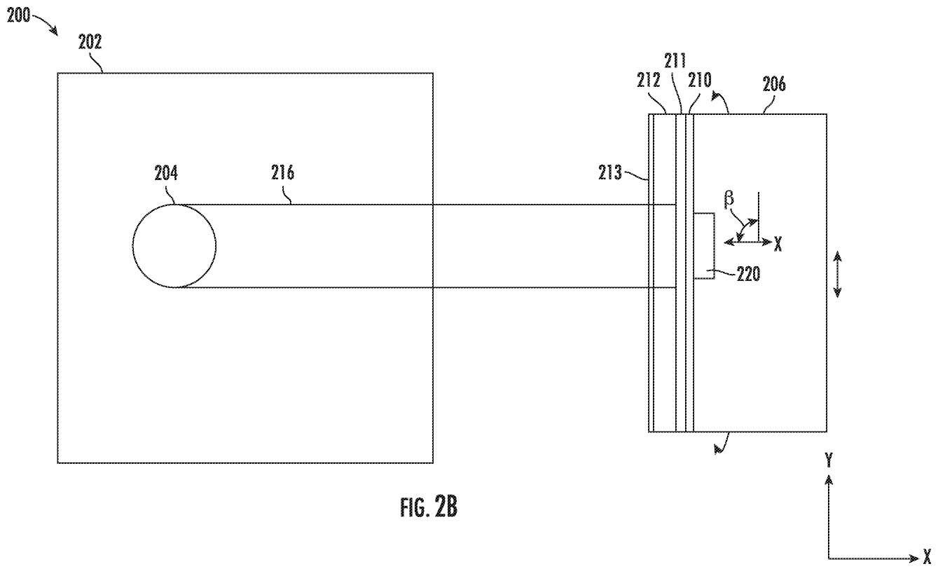

FIG. 2A is a side, schematic cross-sectional view and FIG. 2B is a top, schematic cross-sectional view of an angled etch system (hereinafter “system”) 200, such as the Varian VIISta® system available from Applied Materials, Inc. located in Santa Clara, Calif. It is to be understood that the system 200 described below is an exemplary angled etch system and other angled etch systems, including angled etch systems from other manufacturers, may be used to or modified to form the structures described herein on a substrate.

FIGS. 2A-2B show a device 205 disposed on a platen 206. The device 205 may include a substrate 210, an etch stop layer 211 disposed over the substrate 210, an etching layer to be etched, such as a grating material 212 disposed over the etch stop layer 211, and a hardmask 213 disposed over the grating material 212. It will be appreciated that the device 205 may include different layering materials and/or combinations in other embodiments. For example, the hardmask 213 may not be present in some cases. In another example, the etching layer may be a blanket film to be processed, such as a photoresist-type material or an optically transparent material (e.g., silicon or silicon nitride). The blanket film may be processed using a selective area processing (SAP) etch cycle(s) to form one or more sloped or curved surfaces of the device 205. In another embodiment, the etch stop layer 211 may not be present.

To form structures (e.g., fins) 222 having slant angles, the grating material 212 may be etched by the system 200. In one embodiment, the grating material 212 is disposed on the etch stop layer 211 disposed on the substrate 210. In one embodiment, the one or more materials of the grating material 212 are selected based on the slant angle of each structure to be formed and the refractive index of the substrate 210. In some embodiments, the grating material 212 includes one or more of silicon oxycarbide (SiOC), titanium dioxide (TiO₂), silicon dioxide (SiO₂), vanadium (IV) oxide (VOx), aluminum oxide (Al₂O₃), indium tin oxide (ITO), zinc oxide (ZnO), tantalum pentoxide (Ta₂O₅), silicon nitride (Si₃N₄), titanium nitride (TiN), and/or zirconium dioxide (ZrO₂) containing materials. The grating material 212 can have a refractive index between about 1.5 and about 2.65.

In some embodiments, the hardmask 213 is a non-transparent hardmask that is removed after the device 205 is formed. For example, the non-transparent hardmask 213 can include reflective materials, such as chromium (Cr) or silver (Ag). In another embodiment, the patterned hardmask 213 is a transparent hardmask. In one embodiment, the etch stop layer 211 is a non-transparent etch stop layer that is removed after the device 205 is formed. In another embodiment, the etch stop layer 211 is a transparent etch stop layer.

The system 200 may include an ion beam chamber 202 that houses an ion beam source 204. The ion beam source 204 is configured to generate an ion beam 216, such as a ribbon beam, a spot beam, or full substrate-size beam. The ion beam chamber 202 is configured to direct the ion beam 216 at a first ion beam angle α relative to a surface normal 218 of the substrate 210. Changing the first ion beam angle α may require reconfiguration of the hardware of the ion beam chamber 202. The substrate 210 is retained on a platen 206 coupled to a first actuator 208. The first actuator 208 is configured to move the platen 206 in a scanning motion along a y-direction and/or a z-direction. In one embodiment, the first actuator 208 is further configured to tilt the platen 206, such that the substrate 210 is positioned at a tilt angle β relative to the x-axis of the ion beam chamber 202. In some embodiments, the first actuator 208 can further be configured to tilt the platen 206 relative to the y-axis and/or z-axis.

The first ion beam angle α and the tilt angle β result in a second ion beam angle ϑ relative to the surface normal 218 of the substrate 210 after the substrate 210 is tilted. To form structures having a slant angle ϑ′ relative to the surface normal 218, the ion beam source 204 generates an ion beam 216 and the ion beam chamber 202 directs the ion beam 216 towards the substrate 210 at the first ion beam angle α. The first actuator 208 positions the platen 206, so that the ion beam 216 contacts the grating material 212 at the second ion beam angle ϑ and etches the grating material 212 to form the structures having a slant angle ϑ′ on desired portions of the grating material 212.

Conventionally, to form a portion of structures with a slant angle ϑ′ different than the slant angle ϑ′ of an adjacent portion of structures, or to form structures having a different slant angle ϑ′ on successive substrates, the first ion beam angle α is changed, the tilt angle β is changed, and/or multiple angled etch systems are used. Reconfiguring the hardware of the ion beam chamber 202 to change the first ion beam angle α is complex and time-consuming. Adjusting tilt angle β to modify the ion beam angle ϑ results in non-uniform depths of structures across portions of the substrate 210 as the ion beam 216 contacts the grating material 212 with different energy levels. For example, a portion positioned closer to the ion beam chamber 202 will have structures with a greater depth than structures of an adjacent potion positioned further away from the ion beam chamber 202. Using multiple angled etch systems increases the fabrication time and increases costs due the need of multiple chambers. To avoid reconfiguring the ion beam chamber 202, adjusting the tilt angle β to modify the ion beam angle ϑ, and using multiple angled etch systems, the angled etch system 200 may include a second actuator 220 coupled to the platen 206 to rotate the substrate 210 about the x-axis of the platen 206 to control the slant angle ϑ′ of structures.

During use, the ion beam 216 may be extracted when a voltage difference is applied using a bias supply between the ion beam chamber 202 and substrate 210, or substrate platen, as in known systems. The bias supply may be coupled to the ion beam chamber 202, for example, where the ion beam chamber 202 and substrate 210 are held at the same potential.

The trajectories of ions within the ion beam 216 may be mutually parallel to one another or may lie within a narrow angular spread range, such as within 10 degrees of one another or less. In other embodiments, the trajectory of ions within the ion beam 216 may converge or diverge from one another, for example, in a fan shape. In various embodiments, the ion beam 216 may be provided as a ribbon reactive ion beam extracted as a continuous beam or as a pulsed ion beam, as in known systems.

In various embodiments, gas, such as reactive gas, may be supplied by a source to the ion beam chamber 202. The plasma may generate various etching species or depositing species, depending upon the exact composition of species provided to the ion beam chamber 202. The ion beam 216 may be composed of any convenient gas mixture, including inert gas, reactive gas, and may be provided in conjunction with other gaseous species in some embodiments. In some embodiments, the ion beam 216 and other reactive species may be provided as an etch recipe to the substrate 210 so as to perform a directed reactive ion etching (RIE) of a layer, such as the grating material 212. Such an etch recipe may use known reactive ion etch chemistries for etching materials such as oxide or other material, as known in the art. In other embodiments, the ion beam 216 may be formed of inert species where the ion beam 216 is provided to etch the substrate 210 or more particularly, the grating material 212, by physical sputtering, as the substrate 210 is scanned with respect to ion beam 216.

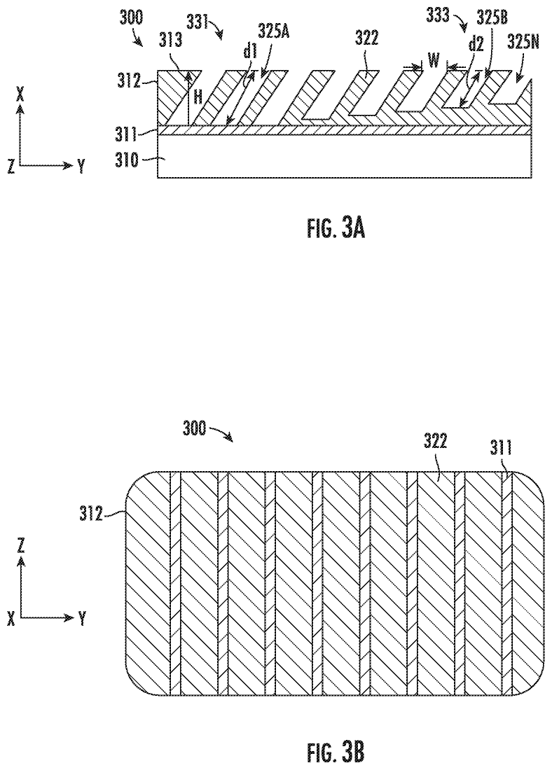

FIG. 3A depicts a side cross sectional view of an optical grating component 300 formed from the grating material 312 according to embodiments of the disclosure. FIG. 3B depicts a frontal view of the optical grating component 300. As shown, the optical grating component 300 includes a substrate 310, and the optical grating material 312 disposed on the substrate 310. The optical grating component 300 may be the same or similar to the input grating 102, the intermediate grating 104, and/or the output grating 106 of FIG. 1. In some embodiments, the substrate 310 is an optically transparent material, such as a known glass. In some embodiments, the substrate 310 is silicon. In the latter case, the substrate 310 is silicon, and another process is used to transfer grating patterns to a film on the surface of another optical substrate, such as glass or quartz. The embodiments are not limited in this context. In the non-limiting embodiment of FIG. 3A and FIG. 3B, the optical grating component 300 further includes an etch stop layer 311, disposed between the substrate 310 and the grating material 312. In other embodiments, no etch stop layer is present between the substrate 310 and the grating material 312.

In some embodiments, the optical grating component 300 may include a plurality of angled structures, shown as angled components or structures 322 separated by trenches 325A-325N. The structures 322 may be disposed at a non-zero angle of inclination (ϕ) with respect to a perpendicular to a plane (e.g., y-z plane) of the substrate 310 and the top surface 313 of the grating material 312. The angled structures 322 may be included within one or more fields of slanted gratings, the slanted grating together forming “micro-lenses.”

In the example of FIG. 3A, the angled structures 322 and the trenches 325A-325N define a variable height along the direction parallel to the y-axis. For example, a depth ‘d1’ of a first trench 325A in a first portion 331 of the optical grating component 300 may be different than a depth ‘d2’ of a second trench 325B in a second portion 333 of the optical grating component 300. In some embodiments, a width of the angled structures 322 and/or the trenches 325 may also vary, e.g., along the y-direction.

The angled structures 322 may be accomplished by scanning the substrate 310 with respect to the ion beam using a processing recipe. In brief, the processing recipe may entail varying at least one process parameter of a set of process parameters, having the effect of changing, e.g., the etch rate or deposition rate caused by the ion beam during scanning of the substrate 310. Such process parameters may include the scan rate of the substrate 310, the ion energy of the ion beam, duty cycle of the ion beam when provided as a pulsed ion beam, the spread angle of the ion beam, and rotational position of the substrate 310. The etch profile may be further altered by varying the ion beam quality across the mask. Quality may include intensity/etch rate such as varying current with duty cycle or beam shape for different angles. In at least some embodiments herein, the processing recipe may further include the material(s) of the grating material 312, and the chemistry of the etching ions of the ion beam. In yet other embodiments, the processing recipe may include starting geometry of the grating material 312, including dimensions and aspect ratios. The embodiments are not limited in this context.

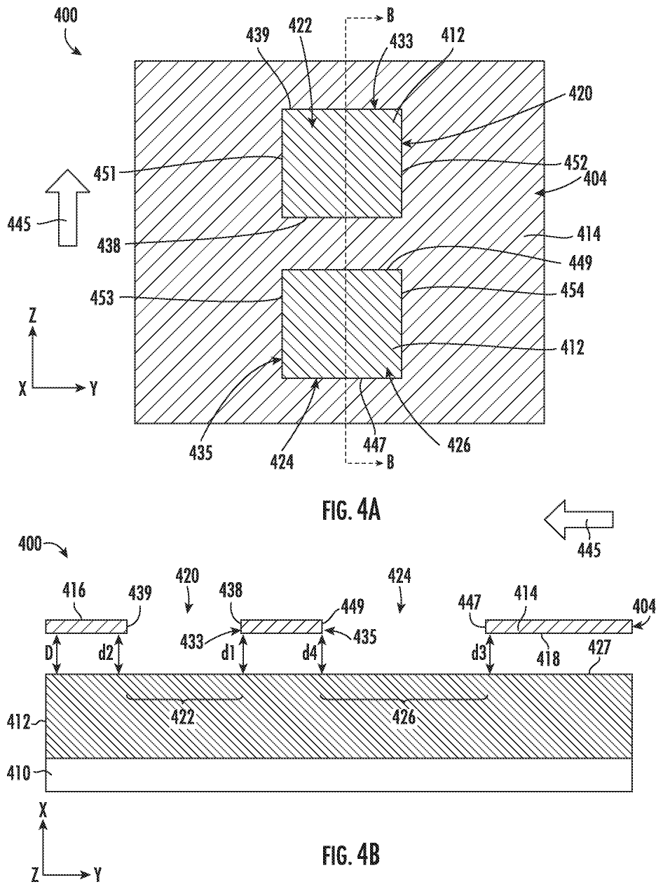

Turning now to FIGS. 4A-8, a process for forming an optical grating device (hereinafter “device”) 400 according to embodiments of the present disclosure will be described in greater detail. As shown in FIGS. 4A-4B, a proximity mask 404 is provided over a substrate layer 412 and a base substrate 410. In some embodiments, the proximity mask 404 may be formed directly atop the base substrate 410 when the substrate layer 412 is not present. The proximity mask 404 may include a plate 414 patterned or otherwise processed to include to a first opening 420, which is positioned over a first processing area 422 of the substrate layer 412, and a second opening 424, which is positioned over a second processing area 426 of the substrate layer 412. It will be appreciated that the first and second processing areas 422, 426 may correspond to areas of the substrate layer 412 where optical gratings or other semiconductor trenches/structures are to be formed. Although not shown, the proximity mask 404 may further include a third opening defining a third processing area.

In some embodiments, the substrate layer 412 may be an optical grating material made from one or more of silicon oxycarbide (SiOC), titanium dioxide (TiO₂), silicon dioxide (SiO₂), vanadium (IV) oxide (VOx), aluminum oxide (Al₂O₃), indium tin oxide (ITO), zinc oxide (ZnO), tantalum pentoxide (Ta₂O₅), silicon nitride (Si₃N₄), titanium nitride (TiN), and/or zirconium dioxide (ZrO₂) containing materials. Although not shown, the substrate layer 412 may be formed over an etch stop layer, which is formed atop the base substrate 410.

The plate 414 may include a first main side 416 opposite a second main side 418, wherein the second main side 418 faces the substrate layer 412. In some embodiments, a plane defined by the first main side 416 may be substantially parallel to a plane defined by the second main side 418. The plate 414 may be separated from a top surface 427 of the substrate layer 412 by a distance ‘D’ (e.g., along the x-direction). The distance D may be constant across the plate 414, or the distance D may vary at different spots along the plate 414. In some embodiments, the plate 414 may be in direct physical contact with the substrate layer 412 at one or more points.

The first opening 420 may be defined by a first perimeter 433 having a first shape, and the second opening 424 may be defined by a second perimeter 435 having a second shape. As will be described in greater detail herein, the first and second shapes may be the same or different. The first perimeter 433 may include a first leading edge 438 and a first trailing edge 439, e.g., relative to a scan direction 445. The first leading edge 438 may be separated from the top surface 427 of the substrate layer 412 by a distance ‘d1’ (e.g., in the x-direction), while the first trailing edge 439 may be separated from the top surface 427 of the substrate layer 412 by a distance ‘d2’. In various embodiments d1 and d2 are the same or different. Similarly, the second perimeter 435 may include a second leading edge 447 and a second trailing edge 449. The second leading edge 447 may be separated from the top surface 427 of the substrate layer 412 by a distance ‘d3’, while the second trailing edge 449 may be separated from the top surface 427 of the substrate layer 412 by a distance ‘d4’. In various embodiments d3 and d4 are the same or different. Furthermore, in various embodiments, d1, d2, d3, and d4 may be the same or different.

As best shown in FIG. 4A, the first perimeter 433 may further include a first side edge 451 and a second side edge 452, while the second perimeter 435 may further include a first side edge 453 and a second side edge 454. Although not shown, the distance between the top surface 427 of the substrate layer 412 and the first and second side edges 452, 453 may be the same or different. Furthermore, the distance between the top surface 427 and any of the edges 451, 452, 453, and 454 may be the same or different. It will be appreciated that the first perimeter 433 and/or the second perimeter 435 may be curved, sloped, stepped, etc. Embodiments herein are not limited in this context.

Next, as shown in FIG. 5, the device 400 may be etched 430 for the purpose of recessing the substrate layer 412 in the first processing area 422 and the second processing area 426. In some embodiments, the etch 430 may be an inductively coupled plasma (ICP) RIE performed/delivered through the first and second openings 420, 424 of the proximity mask 404 at an angle substantially perpendicular to the top surface 427 of the substrate layer 412. In other embodiments, the etch 430 may be performed at a non-zero angle relative to a vertical 431 extending from the top surface 427 of the substrate layer 412. Furthermore, it will be appreciated that the etch 430 may represent one or multiple etch cycles. A density of the plasma may be greatest towards a center of each of the first and second openings 420, 424 resulting in a variable etch rate across the first and second processing areas 422, 426.

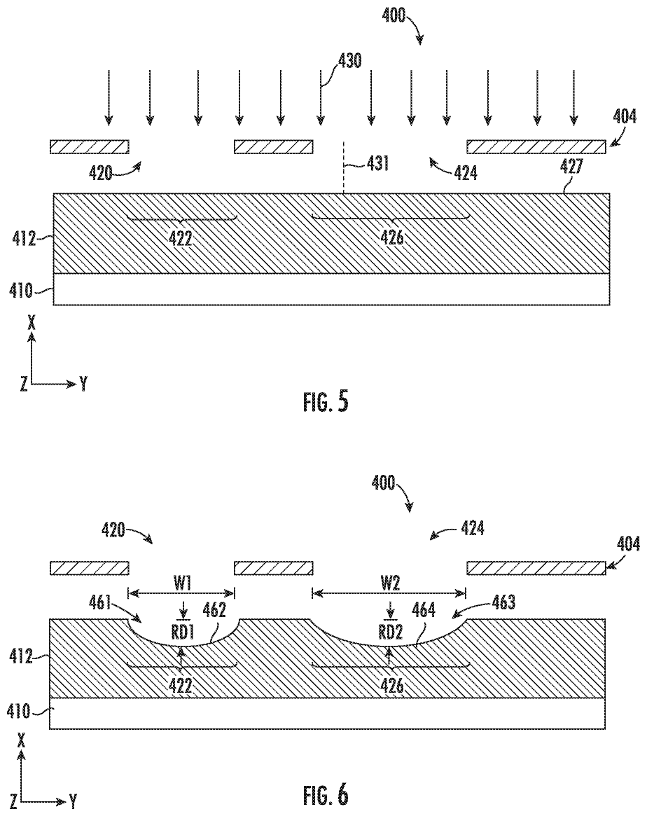

As shown in FIG. 6, as a result of the etch 430, the first processing area 422 may be recessed to a first depth ‘RD1’ to form a first processing trench 461. As shown, a bottom surface 462 of the first processing trench 461 may be curved/non-uniform due to the varied plasma density in the area beneath the first opening 420, which results in a faster etch towards the center/bottommost point of the concave shaped bottom surface 462. The second processing area 426 may be recessed to a second depth ‘RD2’ to form a second processing trench 463. As shown, a bottom surface 464 of the second processing trench 463 may be curved/non-uniform, again due to the varied plasma density in the area beneath the second opening 424, which results in a faster etch towards the center/bottommost point of the concave shaped bottom surface 464. In various embodiments, RD1 and RD2 are the same or different. Furthermore, the first processing trench 461 may have a width ‘W1’, which may be the same or different than a width ‘W2’ of the second processing trench 463.

The device 400 may then be etched 455, as shown in FIG. 7, to form a plurality of structures 460 and a plurality of trenches 462A and 462B, as shown in FIG. 8. In some embodiments, the proximity mask 404 is removed prior to the etch 455. In some embodiments, a patterned hardmask (not shown) may be formed over the substrate layer 412 prior to the etching 455. As shown, the substrate layer 412 may be etched at a non-zero angle ‘β’ relative to the perpendicular 431 extending from the top surface 427 of the substrate layer 412 to form a first set of angled structures 460A in the first processing area 422 and a second set of angled structures 460B in the second processing area 426. As shown, a depth between two or more trenches of the first plurality of trenches 462A may vary. Similarly, a depth between two or more trenches of the second plurality of trenches 462B may vary. In various embodiments, an average width of the first set of structures 460A may be the same or different than an average width of the second set of structures 460B. Furthermore, an angle of the first set of structures 460A may be the same or different than an angle of the second set of structures 460B. Once the first and second sets of structures 460A-460B are complete, the device 400 contains a plurality of diffracted optical elements. Although non-limiting, the first set of structures 460A may correspond to an input grating, while the second set of structures 460B may correspond to an intermediate grating or an output grating.

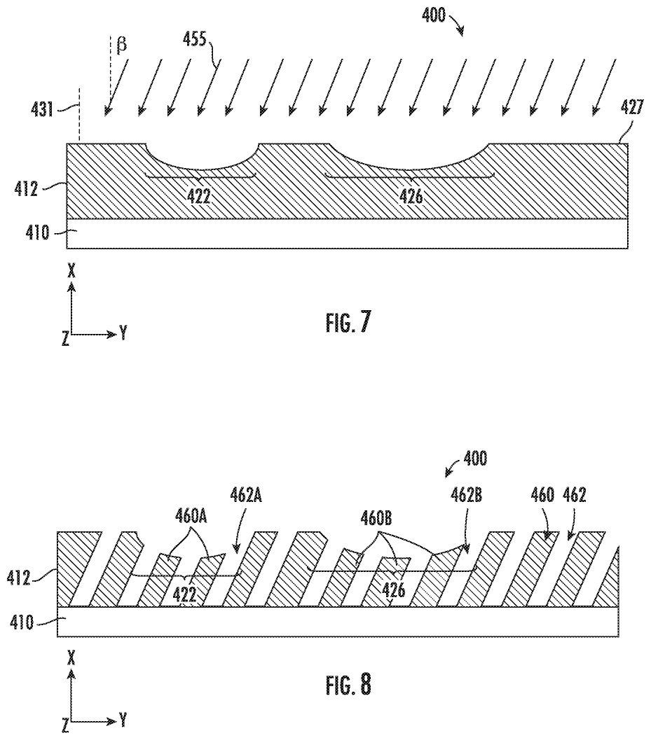

In FIG. 9, a device 500 according to another embodiment of the present disclosure is shown. A proximity mask 504 is provided over a substrate layer 512, such as an optical grating material, and a base substrate 510. The proximity mask 504 may include a plate 514 patterned or otherwise processed to include to a first opening 520, which is positioned over a first processing area 522 of the substrate layer 512, and a second opening 524, which is positioned over a second processing area 526 of the substrate layer 512.

The plate 514 may include a first main side 516 opposite a second main side 518, wherein the second main side 518 faces the substrate layer 512. In some embodiments, a plane defined by the first main side 516 may be substantially parallel to a plane defined by the second main side 518. The plate 514 may be separated from a top surface 527 of the substrate layer 512 by a distance ‘D’. The distance D may vary at different spots along the plate 514. For example, the plane defined by the second main side 518 may be oriented at a non-zero angle ‘ϕ’ relative to a plane defined by the top surface 527 of the substrate layer 512. As such, the first opening 520 may be positioned closer to the substrate layer 512 than the second opening 524.

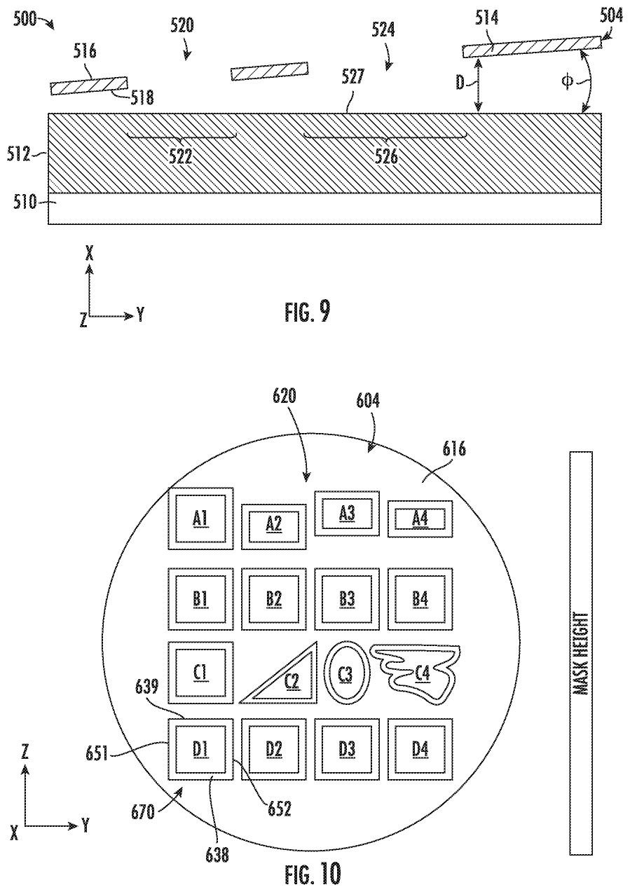

Turning now to FIG. 10, a proximity mask 604 according to embodiments of the present disclosure will be described. The proximity mask 604 may be positioned over a grating material (not shown). The proximity mask 604 may include a plurality of openings 620 formed therein. For the sake of explanation, the openings 620 may be arranged in a series of rows (e.g., A1-14, B1-B4, C1-C4, and D1-D4). It'll be appreciated that the number, arrangement, and/or shape of the openings 620 can vary and is non-limiting. For example, a perimeter defining each of openings A1-A4 may have a constant height/distance (e.g., along the x-direction) relative to the grating material but differ in perimeter size and/or alignment. Conversely, a perimeter defining each of openings B1-B4 may have uniform size/alignment, but differ in distance relative to the grating material. For example, B1 may be positioned closest to the grating material, while B4 may be the farthest. Furthermore, a perimeter defining each of openings C1-C4 may have a constant height/distance relative to the grating material but differ in perimeter shape. Still furthermore, a perimeter defining one or more of openings D1-D4 may have the same size/shape but differ in height/distance relative to the grating material. For example, opening D1 may include a perimeter 670 including a leading edge 638, a trailing edge 639, a first side edge 651, and a second side edge 652. One or more of the leading edge 638, the trailing edge 639, the first side edge 651, and/or the second side edge 652 may vary in height/distance relative to the grating material. Said another way, different portions of the perimeter 670 may be curved, sloped, notched, etc., as desired.

Although not shown, the proximity mask 604 may further include one or more raised surface features along the leading, trailing, and/or side edges of one or more of the openings 620. The raised surface features may extend above a plane defined by a first main side 616 of the proximity mask 604. In some embodiments, the proximity mask 604 may additionally, or alternatively, include surface features extending below a plane defined by a second main side (not shown) of the proximity mask 604. It will be appreciated that the surface features may partially block ion beams, thus influencing an amount, angle, and/or depth the ion beams passing through the openings 610 and impacting the grating material.

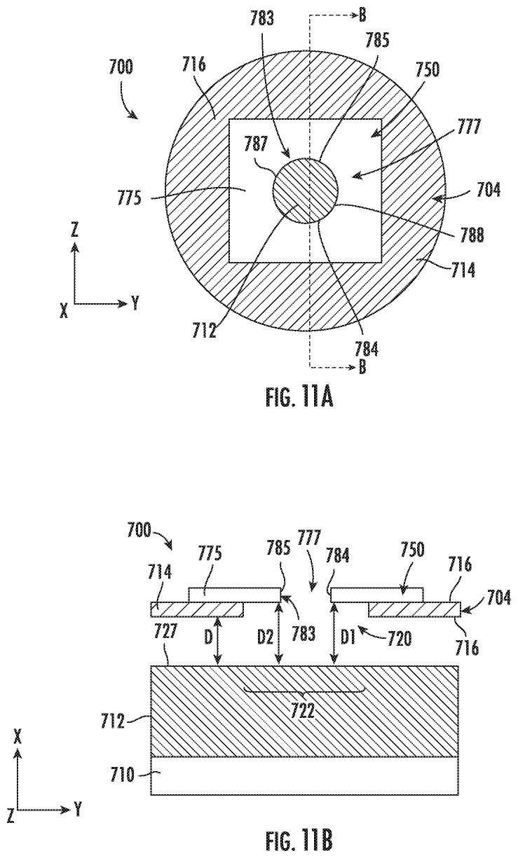

Turning now to FIGS. 11A-11B, a portion of a device 700 including an example stepped feature 750 according to embodiments of the present disclosure will be described. The device 700 may be the same or similar to the devices 400 and 500 described above. As such, only certain aspects of the device 700 will hereinafter be described for the sake of brevity. As shown, a proximity mask 704 is provided over a substrate layer 712, such as an optical grating material, and a base substrate 710. The proximity mask 704 may include a plate 714 patterned or otherwise processed to include to an opening 720, which is positioned over a processing area 722 of the substrate layer 712. Although only a single opening 720 and processing area 722 are demonstrated, it will be appreciated that multiple additional openings and processing areas may be present across the device 700.

The plate 714 may include a first main side 716 opposite a second main side 718, wherein the second main side 718 faces the substrate layer 712. In some embodiments, a plane defined by the first main side 716 may be substantially parallel to a plane defined by the second main side 718. The plate 714 may be separated from a top surface 727 of the substrate layer 712 by a distance ‘D’.

As shown, the proximity mask 704 may include the stepped feature 750 extending across the opening 720. Although non-limiting, the stepped feature 750 may extend from the first main side 716 of the plate 714 (e.g., in the x-direction), and include a planar body 775 extending parallel to the first main side 716. Extending through the planar body 775 is a stepped opening 777. As shown, the stepped opening 777 is generally aligned above the opening 720 of the plate 714. In some embodiments, the stepped feature 750 is directly coupled to the plate 714. In other embodiments, the stepped feature 750 may extend above the plate 714 by some distance. It will be appreciated that the stepped feature 750 may partially block ions, such as ions of an ICP RIE, thus influencing an amount, angle, and/or depth of the ions passing through the stepped opening 777 and the opening 720.

In some embodiments, the stepped opening 777 may be defined by a perimeter 783 including a leading edge 784 and a trailing edge 785, e.g., relative to a scanning direction. The leading edge 784 may be separated from the top surface 727 of the substrate layer 712 by a distance ‘D1’, while the trailing edge 785 may be separated from the top surface 727 of the substrate layer 712 by a distance ‘D2’. In various embodiments D1 and D2 are the same or different. The perimeter 783 may further include a first side edge 787 and a second side edge 788. Although not shown, the distance between the top surface 727 of the substrate layer 712 and the first and second side edges 787, 788 may be the same or different. Furthermore, the distance between the top surface 727 and any of the edges 784, 785, 787, and 788 of the perimeter 783 may be the same or different. Still furthermore, any of the edges 784, 785, 787, and 788 of the perimeter 783 may be curved, sloped, stepped, etc. Embodiments herein are not limited in this context.

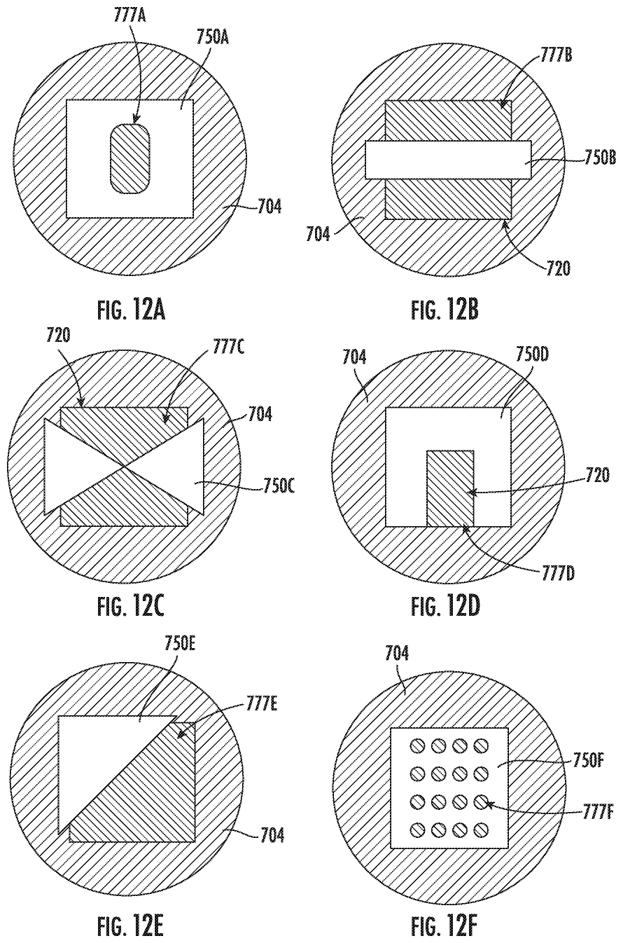

It will be appreciated that the stepped feature 750 may take on a number of shapes, configurations, sizes, etc. For example, FIGS. 12A-12F demonstrate a variety of possible implementations for the stepped feature 750 formed over the opening 720 of the proximity mask 704. In FIG. 12A, stepped feature 750A may generally be rectangular, with stepped opening 777A being oval or a rectangle with rounded corners. In FIG. 12B, stepped feature 750B may be a band or rectangle extending across the opening 720, thus defining multiple stepped openings 777B. In FIG. 12C, stepped feature 750C may take on a dual-triangle or bowtie configuration extending across the opening 720, thus defining multiple stepped openings 777C. In FIG. 12D, stepped feature 750D may include a rectangular stepped opening 777D extending from one side of the opening 720. In FIG. 12E, stepped feature 750E may generally be triangular, leaving a relatively large stepped opening 777E. Finally, in FIG. 12F, stepped feature 750F may be a mesh mask including a plurality of stepped openings 777F. Although non-limiting, the stepped openings 777F may be uniformly positioned across the stepped feature 750F.

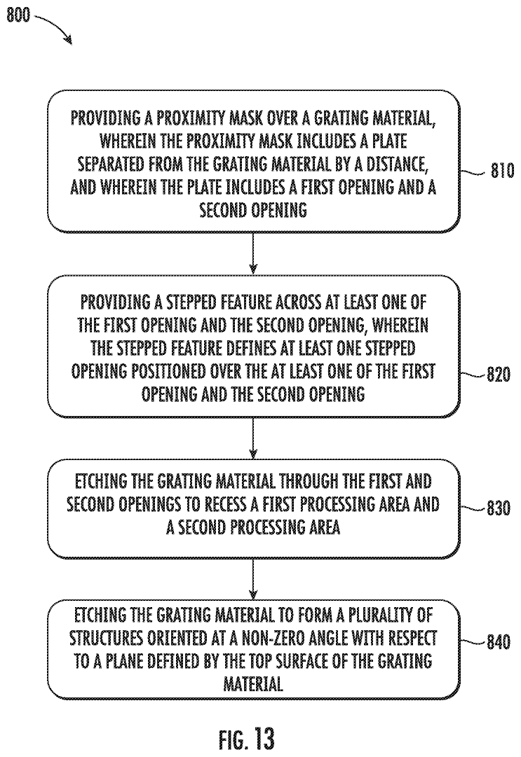

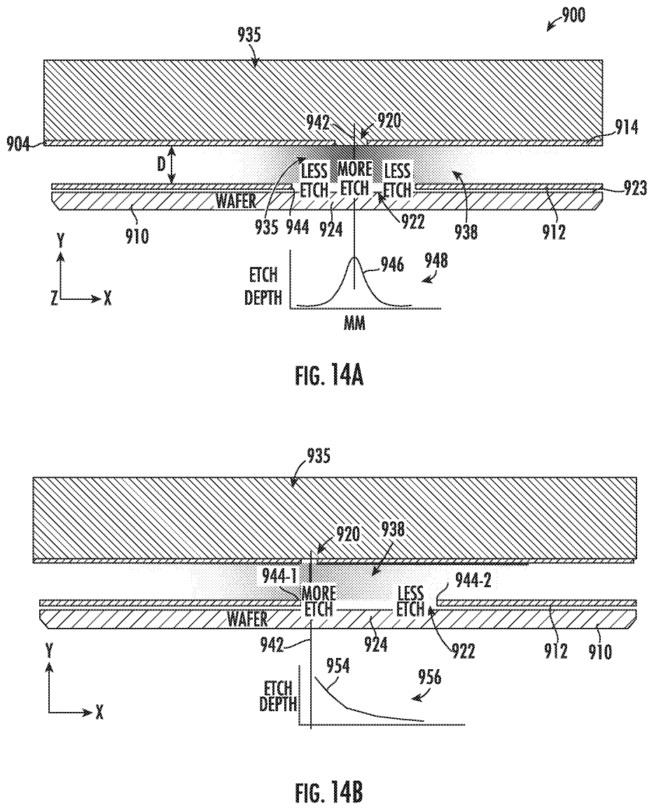

Turning to FIG. 13, a method 800 according to embodiments of the present disclosure will be described. As shown, at block 810, the method 800 may include providing a proximity mask over a substrate and/or grating material, wherein the proximity mask includes a plate separated from the grating material by a distance, and wherein the plate includes a first opening and a second opening. In some embodiments, the plate may include a first main side opposite a second main side, wherein the second main side faces the grating material. In some embodiments, a plane defined by the first main side may be substantially parallel to a plane defined by the second main side. In some embodiments, the plate may be separated from a top surface of the grating material by a constant or varied amount. In some embodiments, the plate may be in direct physical contact with the grating material at one or more points. In some embodiments, the plate at a second non-zero angle relative to the plane defined by the top surface of the grating material.

At block 820, the method 800 may optionally include providing a stepped feature across at least one of the first opening and the second opening, wherein the stepped feature defines at least one stepped opening positioned over the at least one of the first opening and the second opening. In some embodiments, the stepped feature may extend from the first main side of the plate, and include a planar body extending parallel to the first main side. Through the planar body may be a stepped opening. In some embodiments, the stepped feature is directly coupled to the plate. In other embodiments, the stepped feature may extend above the plate by some distance.

At block 830, the method 800 may include etching the grating material through the first and second openings to recess a first processing area and a second processing area. In some embodiments, the etching process may be an ICP RIE process.

At block 840, the method 800 may further include etching the grating material to form a plurality of structures oriented at a non-zero angle with respect to a plane defined by the top surface of the grating material. In some embodiments, the method includes etching the grating material to form a first plurality of trenches in the first processing area and a second plurality of trenches in the second processing area. In some embodiments, the method includes varying an etch depth between two or more trenches of the first plurality of trenches, and varying an etch depth between two or more trenches of the second plurality of trenches. In some embodiments, the method includes removing before the grating material is etched to form the plurality of structures.

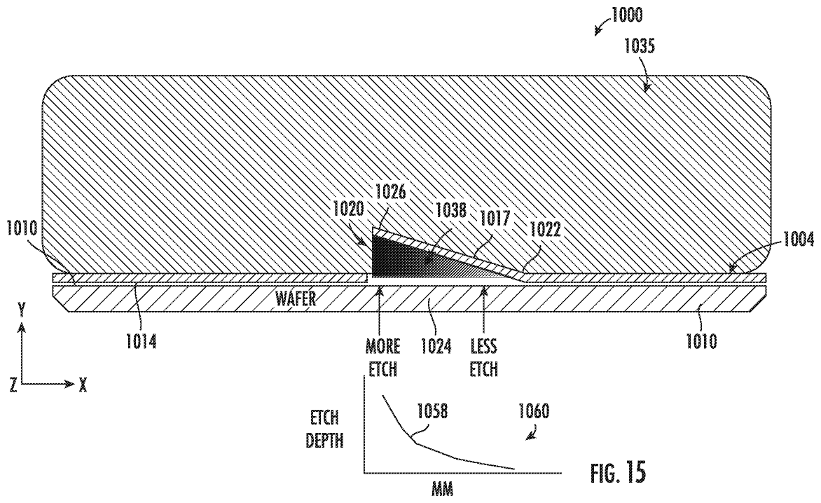

Turning now to FIG. 14A, a portion of a device 900 according to embodiments of the present disclosure will be described. As shown, a proximity mask 904 is provided over a mask layer 912 and a wafer 910. Although not shown, the wafer 910 may include one or more layers, such as an optical grating material. The proximity mask 904 may include a plate 914 patterned or otherwise processed to include to an opening 920, which is positioned over a second opening 922 of the mask layer 912. The second opening 922 may define a processing area 924 of the wafer 910. The plate 914 may be separated from the mask layer 912 by a distance ‘D’. In some embodiments, the mask layer 912 may be further separated from a top surface 923 of the wafer 910 by a space/distance. In other embodiments, the mask layer 912 is formed atop the top surface 923 of the wafer 910. It will be appreciated that the distance ‘D’ may be varied. In some embodiments, the opening 920 and/or the second opening 922 allow for a curved plasma sheath that causes ions of a plasma 935 to converge towards a location on the wafer 910, such as an intended location of the processing area 924.

As shown, density of the plasma 935 above the proximity mask 904 is uniform or substantially uniform. However, in an area 938 between the proximity mask 904 and the mask layer 912, the density of the plasma 935 may vary. For example, density of the plasma 935 may be greatest near an approximate center of the opening 920, as represented by centerline 942. The farther from the centerline 942 (e.g., along +x, −x), the less dense the plasma 935 in the area 938 becomes. As a result, etch rate and/or intensity may be greatest near the centerline 942 and generally less near edges 944 of the second opening 922. The resultant etch depth is demonstrated by gradient profile 946 in graph 948.

As shown in FIG. 14B, the opening 920 through the proximity mask 904 may be varied, e.g., along the x-axis, relative to the second opening 922 and the processing area 924 of the wafer 910. Density of the plasma 935 in the area 938 may be greatest proximate the centerline 942. In this embodiment, density decreases from a first edge 944-1 to a second edge 944-2 of the second opening 922. As a result, etch rate and/or intensity may be greatest near the centerline 942 and the first edge 944-1, and generally less near the second edge 944-2. The resultant etch depth is demonstrated by gradient profile 954 in graph 956.

Turning now to FIG. 15, a proximity mask 1004 of a device 1000 according to another embodiment of the present disclosure will be described. As shown, the proximity mask 1004 is provided over a wafer 1010. The proximity mask 1004 may include a plate 1014 patterned or otherwise processed to include to an opening 1020, which is positioned over a processing area 1024 of the wafer 1010. The plate 1014 may be separated from the wafer 1010 or may be formed directly atop a top surface 1023 of the wafer 1010.

As further shown, the proximity mask 1004 may include a protruding structure or feature 1017, such as a flap, covering, overhang, tab, etc., which extends away from the plate 1014, e.g., in the y-direction. Although non-limiting, the feature 1017 may include a fixed end 1022 coupled to the plate 1014 and a free end 1026 angling away from the plate 1014. As a result, a plasma 1035, which may have a uniform density above the plate 1014, may have a gradient density in an area 1038 beneath the feature 1017 and above the processing area 1024. Said another way, the plasma 1035 in the area 1038 may be denser near the free end 1026 and less dense near the fixed end 1022. As a result, etch rate and/or intensity may be greatest near the entrance to the opening 1020, decreasing towards the fixed end 1022. The resultant etch depth is demonstrated by gradient profile 1058 in graph 1060.

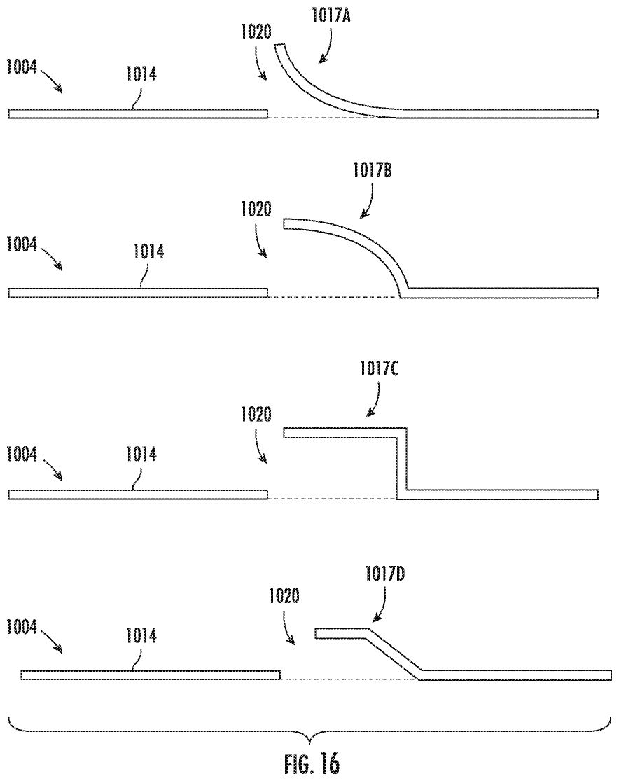

It will be appreciated that the feature 1017 of the proximity mask 1004 may take on a variety of shapes and configurations in various embodiments. Some non-limiting examples of the feature (i.e., 1017A-1017D) are demonstrated in FIG. 16. By varying the shape, configuration, and/or distance of the feature 1017 from the plate 1014, as well as by varying a width, height and/or size of the opening 1020, the plasma density gradient in the area beneath the feature 1017 and above the processing area may also be varied.

In sum, by utilizing the embodiments described herein, a substrate (e.g., waveguide) with regions of variable etch depth is formed. A first technical advantage of the waveguide of the present embodiments includes improved manufacturing efficiency by eliminating more time consuming and difficult processes. Further, a second technical advantage of the grating structures of the present embodiments includes providing a two dimensional or a three-dimensional shape, enabling use of the waveguide in an increased range of applications.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

In various embodiments, design tools can be provided and configured to create the datasets used to pattern the layers of the grating material and the diffracted optical elements described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the description, the various features and functionality described herein may be implemented in any given application. Furthermore, the various features and functionality can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A proximity mask, comprising:
a plate positioned over a substrate, wherein at least a portion of the plate is separated from the substrate by a distance; and
a first opening and a second opening formed through the plate, wherein the first opening is defined by a first perimeter having a first shape, wherein the second opening is defined by a second perimeter having a second shape, and wherein the first shape is different than the second shape.

2. The proximity mask of claim 1, further comprising a stepped feature extending across at least one of the first opening and the second opening.

3. The proximity mask of claim 2, wherein the stepped feature defines at least one stepped opening positioned over the at least one of the first opening and the second opening.

4. The proximity mask of claim 2, wherein the plate includes a first main side opposite a second main side, wherein the stepped feature extends from the first main side, and wherein the second main side of the plate faces the substrate.

5. The proximity mask of claim 4, wherein a plane defined by the second main side of the plate is oriented at a non-zero angle relative to a plane defined by a top surface of the substrate.

6. The proximity mask of claim 4, wherein the stepped feature includes a leading edge and a trailing edge, and wherein a step distance between the first main side of the plate and the stepped feature varies between the leading and trailing edges.

7. The proximity mask of claim 1, wherein the first perimeter includes a first leading edge and a first trailing edge, wherein a first distance between the first leading edge and the substrate is different than a second distance between the first trailing edge and the substrate.

8. The proximity mask of claim 7, wherein the first perimeter further includes a first side edge and a second side edge, wherein a third distance between the first side edge and the substrate is different than fourth distance between the second side edge and the substrate.

9. The proximity mask of claim 1, further comprising a structure extending across at least one of the first opening and the second opening, wherein the structure extends away from the plate.

10. A method, comprising:
providing a proximity mask over a substrate, wherein the proximity mask includes a plate separated from the substrate by a distance, and wherein the plate includes a first opening and a second opening;
etching the substrate through the first and second openings to recess a first processing area and a second processing area; and
etching the substrate to form a plurality of structures oriented at a non-zero angle with respect to a perpendicular to a plane defined by a top surface of the substrate.

11. The method of claim 10, further comprising extending a stepped feature across at least one of the first opening and the second opening, wherein the stepped feature defines at least one stepped opening positioned over the at least one of the first opening and the second opening.

12. The method of claim 10, further comprising orienting the plate at a second non-zero angle relative to the plane defined by the top surface of the substrate.

13. The method of claim 10, further comprising etching the substrate through the first and second openings to form the first processing area or the second processing area with a variable depth.

14. The method of claim 13, further comprising varying an etch depth between two or more trenches of the first plurality of trenches, and varying an etch depth between two or more trenches of the second plurality of trenches.

15. The method of claim 10, further comprising varying an etch depth across the first processing area and a second processing area.

16. A method, comprising:
providing an ion beam source within a chamber, wherein the chamber is operable to deliver an ion beam to a substrate;
providing a proximity mask over the substrate, wherein the proximity mask includes a plate separated from the substrate by a distance, and wherein the plate includes a first opening and a second opening;
etching the substrate through the first and second openings to recess a first processing area and a second processing area; and
etching the substrate to form a plurality of structures oriented at a non-zero angle with respect to a perpendicular to a plane defined by a top surface of the substrate.

17. The method of claim 16, further comprising extending a stepped feature across at least one of the first opening and the second opening, wherein the stepped feature defines at least one stepped opening positioned over the at least one of the first opening and the second opening.

18. The method of claim 16, further comprising orienting the plate at a second non-zero angle relative to the plane defined by the top surface of the substrate.

19. The method of claim 16, further comprising etching the substrate to form a first plurality of trenches in the first processing area and a second plurality of trenches in the second processing area, wherein an etch depth between two or more trenches of the first plurality of trenches is different, and wherein an etch depth between two or more trenches of the second plurality of trenches is different.

20. The method of claim 19, further comprising removing the proximity mask after the first and second processing areas are recessed and before the substrate is etched to form the first plurality of trenches in the first processing area and the second plurality of trenches in the second processing area.
